(19) United States
(12) Patent Application Publication
(10) Pub. No.: US 2002/0192941 A1
(43) Pub. Date: Dec. 19, 2002

(54) Method for reducing dishing in copper chemical mechanical polishing process

(76) Inventors: Chia-Lin Hsu, Taipei City (TW); Art Yu, Kaohsiung (TW); Shao-Chung Hu, Taipei City (TW); Teng-Chun Tsai, Hsin-Chu City (TW)

Correspondence Address: POWELL, GOLDSTEIN, FRAZER & MURPHY LLP, P.O. BOX 97223, WASHINGTON, DC, 20090-7223, US

(21) Appl. No.: 09/884,800

(22) Filed: Jun. 19, 2001

(51) Int. Cl. H01L 21/4763; H01L 21/44

(52) U.S. Cl. 438/633; 438/626; 438/645

(57) ABSTRACT

The present invention provides a method of reducing dishing and erosion of a conductive structure in the process of chemical mechanical polishing. The method comprises providing a dielectric layer having at least a via hole thereon. A barrier layer is formed on the dielectric layer and the via hole. A conductive layer, such as copper layer, is formed on the barrier layer and filled into the via hole to form the conductive structure. The partial conductive layer is removed to expose the partial barrier layer. The exposed barrier layer and the conductive structure are polished. The polishing step is implemented by using a reagent whereby a metallic compound is formed on the conductive structure for protecting the conductive structure against dishing and erosion.

### BACKGROUND OF THE INVENTION

1. Field of the Invention

The present invention relates to a method of fabrication used in o the semiconductor integrated circuit devices, and more particularly relates to a method for planarizing conductive copper lines and interconnects by using the process of chemical mechanical polishing (CMP).

2. Description of the Prior Art

It is the nature of semiconductor physics that as the feature sizes are scaled down, the performance of internal devices in integrated circuits improves in a compounded fashion. That is, the device speed as well as the functional capability improves. The overall circuit speed, however, becomes more dependent upon the propagation speed of the signals along the interconnects that connect the various devices together. With the advent of very and ultra large scale integration (VLSI and ULSI) circuits, it has therefore become even more important that the metal conductors that form the interconnections between devices as well as between circuits in a semiconductor have low resistivity for high signal propagation. Copper is often preferred for its low resistivity, as well as for resistance to electromigration and stress voiding properties.

The process of chemical mechanical polishing (CMP) is used for planarizing or removing copper and any surrounding material at the same time. Key to the CMP process is the polishing rates of copper and the surrounding materials. The softer surface of copper metal is typically polished back at a faster rate than the surrounding material is, which causes dishing in the copper structures. This lack of planarity because of dishing results from the differently polishing rates of CMP on the different materials, which presents a challenge to the semiconductor industry. Ideally, the CMP polishing rate of copper and that of the surrounding material should be similar, such that copper is polished without any dishing and stopped on the surrounding insulating layer without removing the insulating layer.

### SUMMARY OF THE INVENTION

It is an object of the invention to provide a method for reducing dishing and erosion in the process of copper chemical mechanical polishing. A protective film of copper composition is formed during the removal of stop layer in the process of chemical mechanical polishing which reduces the polishing rate of copper and is easily removed during post-cleaning step.

It is another object of the invention to provide a method for raising quality of process window in a dual-damascene process. The dishing and erosion of copper conductors and interconnection can be reducing by adding the reagent of copper-compound formation into the slurry during the removal of stop layer in the chemical mechanical polishing.

The present invention provides a method of reducing dishing and erosion of a conductive structure in the process of chemical mechanical polishing. The method comprises providing a dielectric layer having at least a via hole thereon. A barrier layer is formed on the dielectric layer and the via hole. A conductive layer, such as copper layer, is formed on the barrier layer and filled into the via hole to form the conductive structure. The partial conductive layer is removed to expose the partial barrier layer. The exposed barrier layer and the conductive structure are polished. The polishing step is implemented by using a reagent whereby a metallic compound is formed on the conductive structure for protecting the conductive structure against dishing and erosion.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIGS. 1A-1D are schematic representations of planarizing a conducting interconnect by using a chemical mechanical polish (CMP) process, in accordance with the present invention;

FIG. 2 is the schematic representation of the chemical mechanism polishing process, in accordance with the present invention; and

FIG. 3 is a curve illustrating the relationship of the concentration of the reagent and copper dishing in accordance with the present invention.

### DESCRIPTION OF THE PREFERRED EMBODIMENT

The semiconductor devices of the present invention are applicable to a broad rang of semiconductor devices and can be fabricated from a variety of semiconductor materials. The following description discusses several presently preferred embodiments of the semiconductor devices of the present invention as implemented in silicon substrates, since the majority of currently available semiconductor devices are fabricated in silicon substrates and the most commonly encountered applications of the present invention will involve silicon substrates. Accordingly, application of the present invention is not intended to be limited to those devices fabricated in silicon semiconductor materials, but will include those devices fabricated in one or more of the available semiconductor materials.

A method for planarizing a copper structure by using a chemical mechanical polish (CMP) process is provided. The method comprises providing a semiconductor structure having at least a via hole thereon. A barrier layer is conformally formed on the semiconductor structure and the via hole. A copper layer is formed on the barrier layer and filled into the via hole to form the copper structure. The partial copper layer is removed to expose the partial barrier layer. The exposed barrier layer and the copper structure are polished by using a slurry solution containing a reagent whereby a copper compound is formed by reacting with the copper structure.

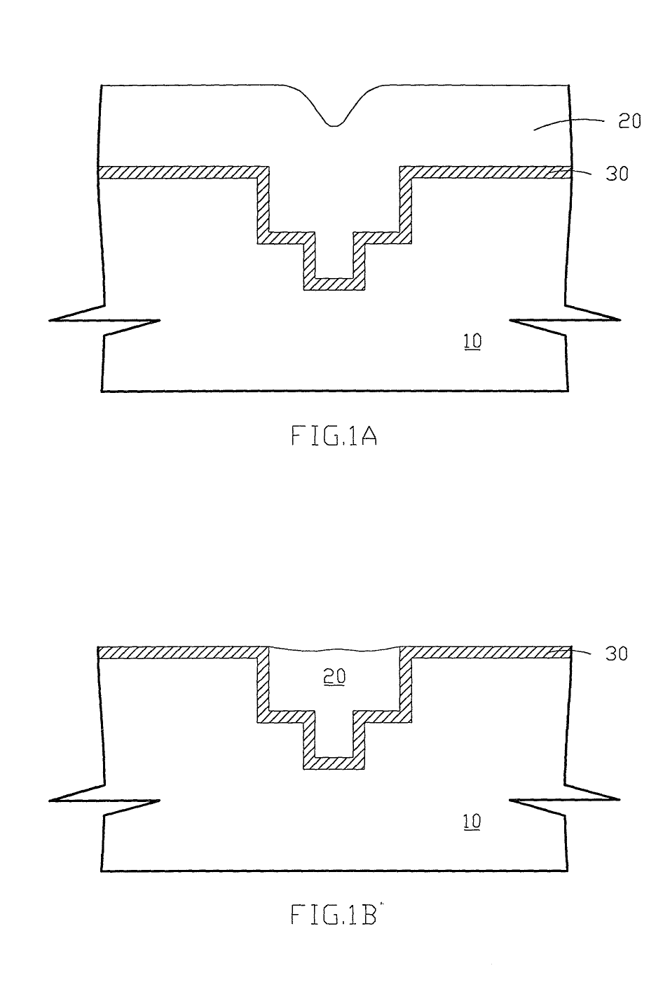

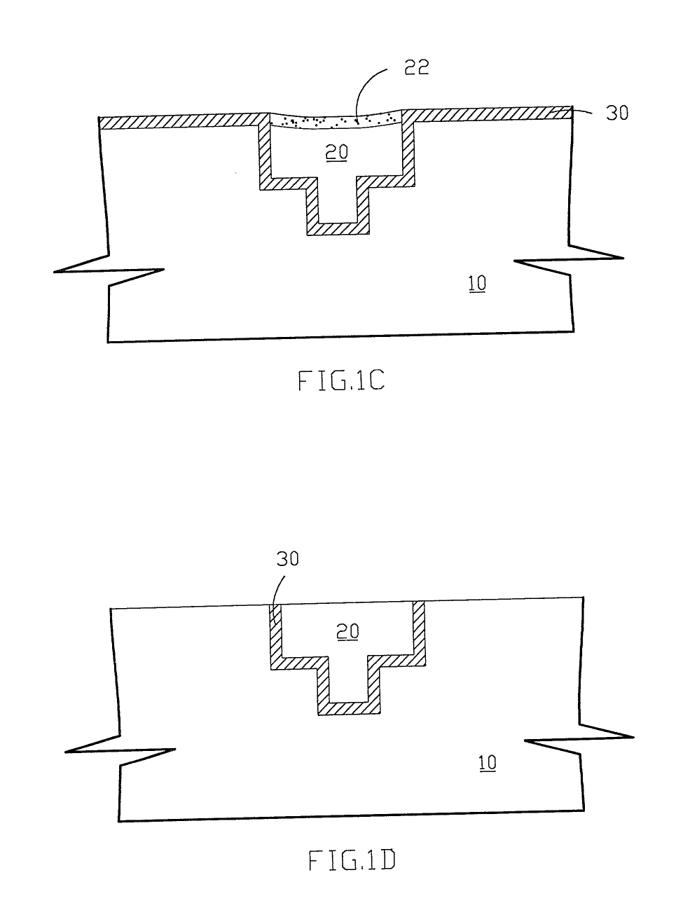

A series of process steps were introduced to planarize copper interconnection by using a chemical mechanism polishing process shown in FIG. 1A to FIG. 1D.

Referring to FIG. 1A, a dielectric layer 10, such as a low-k dielectric layer on a semiconductor structure (not shown), has a via hole which is used as an interconnection and formed by using a dual-damascene process. A barrier layer 30, such as Ta or TaN layer, acting as a liner layer conformally covers on the surfaces of the dielectric layer 10 and the via hole. For low film stress, good coverage and good adhesion, the preferred formation method of the barrier layer 30 is the physical vapor deposition. Next a metal layer 20, such as a copper layer, is deposited over the barrier layer 30 and filled into the via hole. The o metal layer 20 can be formed by using physical vapor deposition, chemical vapor deposition, or electroplating.

Illustrated in FIG. 1B, the excess metal layer 20 is removed by using the chemical mechanical polishing and stopped on the barrier layer 30. The metal layer 20 is typically polished back at a faster rate than the surrounding barrier layer 30 is, which results in little dishing on the metal layer 20.

Next, as a key step of the present invention, a slurry solution containing a reagent of metal-compound formation is used in the removal of the barrier layer 30 on the dielectric layer 10. The metal layer 20 is reacted with the reagent in the slurry solution to form a metallic compound layer 22 on the surface of the metal layer 20 in the interconnection hole, shown in FIG. 1C. In the present invention, the metallic compound layer 22 is a copper compound layer. In the preferred embodiment, the pH value of the slurry solution is about between 7 and 12. The reagent in the slurry solution can be potassium iodate, hydrogen peroxide, ferric nitrate, and ammonium persulfate. The reagent in the slurry solution has an equivalent concentration in the range of about 0.05N and 3N. The metallic compound layer 22 can effectively protect the metal layer 20 from polishing at a faster polishing rate in the second CMP process for removal of the barrier layer 30.

Then shown in FIG. 1D, the metallic compound layer 22 can be simultaneously polished with the barrier layer 30 and easily removed in the following step, such as a post cleaning process after the CMP process. The dishing or erosion of the metal layer 20 is reduced by the formation of the metallic compound layer 22.

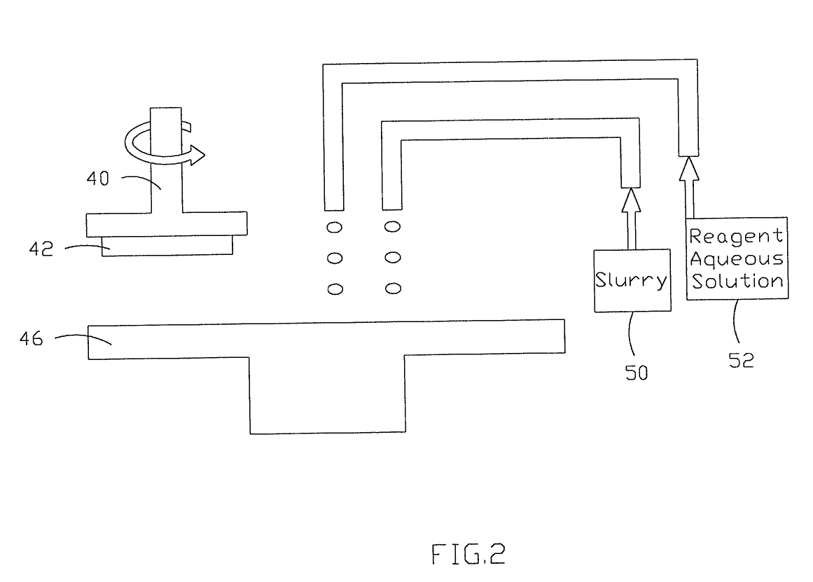

Referring to FIG. 2, the schematic representation is the CMP process in accordance with the present invention. A wafer 42 is attached by a holder 40 and then polished on a polishing pad 46 with a slurry solution containing a reagent. The reagent may be added into any suitable commercialization slurry to prepare the slurry solution of the present invention. Alternatively, the reagent is also prepared as a reagent aqueous solution 52 separated from a slurry solution 50. The reagent aqueous solution 52 has a suitable concentration and a pH value similar to those of the slurry solution 52. Then the reagent aqueous solution 52 and the slurry solution 50 are in-situ mixed on the polishing pad 46.

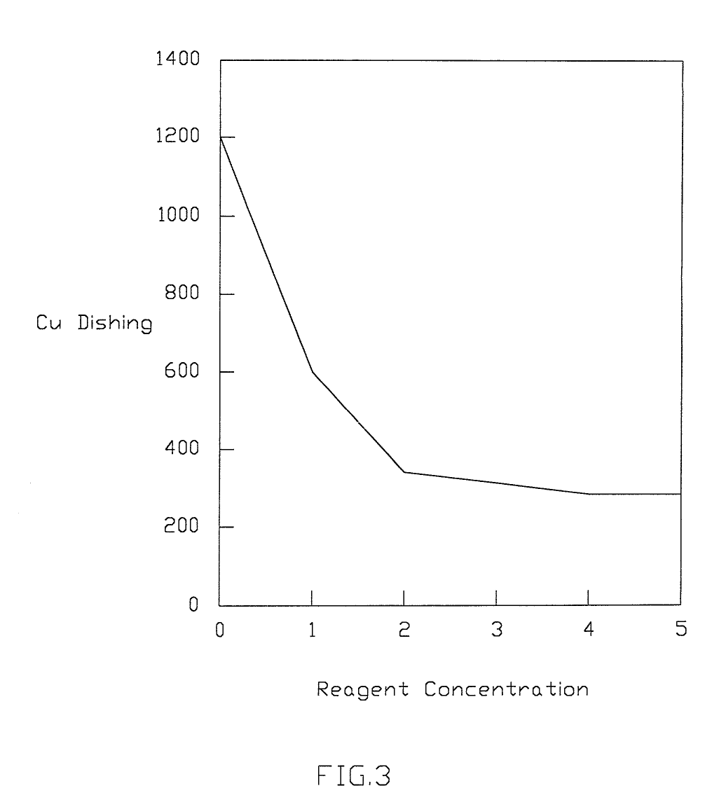

FIG. 3 illustrates the relationship of the concentration (Au, absolute unit) of the reagent and the depth (Angstrom) of the copper dishing. The depth reduction of copper dishing illustrates that the formation of the copper compound can improve the copper dishing and avoid copper erosion.

Of course, it is to be understood that the invention need not be limited to these disclosed embodiments. Various modification and similar changes are still possible within the spirit of this invention. In this way, the scope of this invention should be defined by the appended claims.

What is claimed is:

1. A method of reducing dishing and erosion of a conductive structure in the process of chemical mechanical polishing, said method comprising:
providing a dielectric layer having at least a via hole thereon;
forming a barrier layer on said dielectric layer and said via hole;
forming a conductive layer on said barrier layer and filling into said via hole to form said conductive structure;
removing partial said conductive layer to expose partial said barrier layer; and
polishing exposed said barrier layer and said conductive structure, said polishing step implemented by using a reagent whereby a metallic compound is formed on said conductive structure for protecting said conductive structure against dishing and erosion.

2. The method according to claim 1, wherein said dielectric layer comprises a low-dielectric-constant dielectric layer.

3. The method according to claim 1, wherein said conductive layer comprises a copper layer.

4. The method according to claim 1, wherein said reagent comprises contained in a slurry solution that has a pH value in a range of about 7 to 12.

5. The method according to claim 4, wherein said reagent has an equivalent concentration in a range of about 0.05N to 3N.

6. The method according to claim 1, wherein said reagent is selected from the group of potassium iodate, hydrogen peroxide, ferric nitride, and ammonium persulfate.

7. The method according to claim 1, wherein said metallic compound constitutes a film that reduces a polishing rate of said conductive structure.

8. The method according to claim 1 further comprising removing said metallic compound in a post-cleaning process.

9. A method for planarizing a copper structure by using a chemical mechanical polish (CMP) process, said method comprising:
providing a semiconductor structure having at least a via hole thereon;
conformally forming a barrier layer on said semiconductor structure and said via hole;
forming a copper layer on said barrier layer and filling into said via hole to form said copper structure;
removing partial said copper layer to expose partial said barrier layer; and
polishing exposed said barrier layer and said copper structure by using a slurry solution containing a reagent whereby a copper compound is formed by reacting with said copper structure.

10. The method according to claim 9, wherein said barrier layer reduces a polishing rate of said copper layer.

11. The method according to claim 9, wherein said slurry solution has a pH value in a range about 7 to 12.

12. The method according to claim 9, wherein said reagent in said slurry solution has an equivalent concentration in a range about 0.05N to 3N.

13. The method according to claim 9, wherein said reagent is selected from the group of potassium iodate, hydrogen peroxide, ferric nitride, and ammonium persulfate.
